(19) United States
(12) Patent Application Publication
(10) Pub. No.: US 2016/0005923 A1
(43) Pub. Date: Jan. 7, 2016

(54) LED ELEMENT AND MANUFACTURING METHOD FOR SAME

(71) Applicant: EL-SEED CORPORATION, Nagoya-shi, Aichi (JP)

(72) Inventors: Atsushi SUZUKI, Nagoya-shi, Aichi (JP); Koichi NANIWAE, Nagoya-shi, Aichi (JP); Johan EKMAN, Nagoya-shi, Aichi (JP)

(73) Assignee: EL-SEED CORPORATION, Nagoya-shi, Aichi (JP)

(21) Appl. No.: 14/763,342

(22) PCT Filed: Feb. 7, 2014
(86) PCT No.: PCT/JP2014/052894

§ 371 Date: Aug. 31, 2015

(30) Foreign Application Priority Data
Feb. 12, 2013 (JP) 2013-025014

(51) Int. Cl. H01L 33/20; H01L 33/32; H01L 33/00; H01L 33/46; H01L 33/36

(52) U.S. Cl. CPC H01L 33/20; H01L 33/46; H01L 33/36; H01L 33/007; H01L 33/32; H01L 2933/0025; H01L 2933/0016

(57) ABSTRACT

An LED element capable of further improving the light extraction efficiency and a manufacturing method for the same are provided.

In an LED element, a front surface of a sapphire substrate foams a verticalized moth eye surface having a plurality of depression parts or projection parts whose period is greater than twice an optical wavelength of light emitted from a light-emitting layer and smaller than coherent length, and a light whose intensity distribution is adjusted by reflecting on and transmitting through the verticalized moth eye surface to be inclined to a vertical direction with respect to an interface between a semiconductor lamination unit and the sapphire substrate is discharged from a transmission moth eye surface to an outer side of the element with Fresnel reflection being inhibited.

### TECHNICAL FIELD

The present invention relates to an LED element and a manufacturing method for the same.

### BACKGROUND ART

An LED element provided with a group III nitride semiconductor that is found on the front surface of a sapphire substrate and that includes a light-emitting layer, a diffraction surface that is provided on the front surface side of the sapphire substrate, that allows incidence of light emitted from the light-emitting layer, and that has depression parts or projection parts whose period is grater than an optical wavelength of the light and is smaller than coherent length of the light, and an Al reflection layer that is formed on the back surface side of the substrate, that causes the light diffracted at the diffraction surface to reflect and to be incident on the diffraction surface again is known (refer to Patent Literature 1). With this LED element, light transmitted by diffraction operation is incident on the diffraction surface again, and transmitted through the diffraction surface by using the diffraction operation again, so that the light can be extracted to the outside of the element in a plurality of modes.

### CITATION LIST

### Patent Literature

Patent Literature 1: WO2011/027679

### SUMMARY OF INVENTION

### Technical Problem

The present inventors have pursued further improvement in light extraction efficiency.

The present invention is made in view of the above-described circumstances, and its object is to provide an LED element capable of further improving the light extraction efficiency, and a manufacturing method for the same.

### Solution to Problem

In order to achieve the above-described object, provided according to the present invention is an LED element of a flip chip type, including: a sapphire substrate; a semiconductor lamination unit that is formed on a front surface of the sapphire substrate and that includes a light-emitting layer; and a reflection unit that is formed on the semiconductor lamination unit, in which the front surface of the sapphire substrate forms a verticalized moth eye surface having a plurality of depression parts or projection parts whose period is greater than twice an optical wavelength of light emitted from the light-emitting layer and smaller than coherent length, in which a back surface of the sapphire substrate forms a transmission moth eye surface having depression parts or projection parts whose period is smaller than twice the optical wavelength of light emitted from the light-emitting layer, in which the verticalized moth eye surface reflects and transmits light being incident on the verticalized moth eye surface from a side of the semiconductor lamination unit, and is configured in such a manner that, in an angle region exceeding a critical angle, intensity distribution of light emitted by reflection from the verticalized moth eye surface on the side of the semiconductor lamination unit is inclined to direction closer to vertical direction with respect to an interface between the semiconductor lamination unit and the sapphire substrate, as compared with the intensity distribution of light being incident on the verticalized moth eye surface on the side of the semiconductor lamination unit, and that, in the angle region exceeding the critical angle, the intensity distribution of light emitted by transmission from the verticalized moth eye surface on a side of the sapphire substrate is inclined to direction closer to the vertical direction with respect to the interface, as compared with the intensity distribution of light being incident on the verticalized moth eye surface on the side of the semiconductor lamination unit, and in which the light, whose intensity distribution is adjusted by reflecting on and transmitting through the verticalized moth eye surface to be inclined to the vertical direction with respect to the interface, is discharged from the transmission moth eye surface to an outer side of the element with Fresnel reflection being inhibited.

According to the above-described LED element of the flip chip type, reflectivity of the reflection unit may be increased as an angle comes closer to the direction vertical to the interface.

Further, in order to achieve the above-described object, provided is a manufacturing method of an LED element for manufacturing the above-described LED element, the manufacturing method including: a mask layer formation process that forms a mask layer on a front surface of a sapphire substrate; a resist film formation process that forms a resist film on the mask layer; a pattern formation process that forms a predetermined pattern on the resist film; a resist alteration process that guides plasma of an Ar gas to a side of the sapphire substrate by applying predetermined bias output, and that alters the resist film by the plasma of the Ar gas, so as to increase etch selectivity; a mask layer etching process that guides the plasma of the Ar gas to the side of the sapphire substrate by applying bias output higher than the bias output of the resist alteration process, and that uses the resist film, whose etch selectivity is increased, as a mask, so as to etch the mask layer; a substrate etching process that uses the etched mask layer as a mask, and that etches the sapphire substrate, so as to form the depression parts or the projection parts; a semiconductor formation process that forms the semiconductor lamination unit on the etched front surface of the sapphire substrate; and a multilayer formation process that forms the dielectric multilayer film on a back surface of the sapphire substrate.

According to the above-described manufacturing method of the LED element, the sapphire substrate may be etched while the resist film remains on the mask layer, in the substrate etching process.

According to the above-described manufacturing method of the LED element, the mask layer includes a SiO₂ layer on the sapphire substrate and a Ni layer on the SiO₂ layer, and, in the substrate etching process, the sapphire substrate may be etched while the SiO₂ layer, the Ni layer, and the resist film are laminated.

Further, in order to achieve the above-described object, provided is an LED element of a face-up type, including: a sapphire substrate; a semiconductor lamination unit that is formed on a front surface of the sapphire substrate and that includes a light-emitting layer; a reflection unit that is formed on a back surface of the sapphire substrate; and an electrode that is formed on the semiconductor lamination unit, in which the front surface of the sapphire substrate forms a verticalized moth eye surface having a plurality of depression parts or projection parts whose period is greater than twice an optical wavelength of light emitted from the light-emitting layer and smaller than coherent length, in which a front surface of the electrode forms a transmission moth eye surface having depression parts or projection parts whose period is smaller than twice the optical wavelength of light emitted from the light-emitting layer, in which the verticalized moth eye surface reflects and transmits light being incident on the verticalized moth eye surface from a side of the semiconductor lamination unit, and is configured in such a manner that, in an angle region exceeding a critical angle, intensity distribution of light emitted by reflection from the verticalized moth eye surface on the side of the semiconductor lamination unit is inclined to direction closer to vertical direction with respect to an interface between the semiconductor lamination unit and the sapphire substrate, as compared with the intensity distribution of light being incident on the verticalized moth eye surface on the side of the semiconductor lamination unit, and that, in the angle region exceeding the critical angle, the intensity distribution of light emitted by transmission from the verticalized moth eye surface on a side of the sapphire substrate is inclined to direction closer to the vertical direction with respect to the interface, as compared with the intensity distribution of light being incident on the verticalized moth eye surface on the side of the semiconductor lamination unit, and in which the light, whose intensity distribution is adjusted by reflecting on and transmitting through the verticalized moth eye surface to be inclined to the vertical direction with respect to the interface, is discharged from the transmission moth eye surface to an outer side of the element with Fresnel reflection being inhibited.

Furthermore, in order to achieve the above-described object, provided is an LED element including: a sapphire substrate; and a semiconductor lamination unit that is formed on a front surface of the sapphire substrate and that includes a light-emitting layer, in which the front surface of the sapphire substrate forms a verticalized moth eye surface having a plurality of depression parts or projection parts whose period is greater than twice an optical wavelength of light emitted from the light-emitting layer and smaller than coherent length, in which the verticalized moth eye surface reflects and transmits light being incident on the verticalized moth eye surface from a side of the semiconductor lamination unit, and is configured in such a manner that, in an angle region exceeding a critical angle, intensity distribution of light emitted by reflection from the verticalized moth eye surface on the side of the semiconductor lamination unit is inclined to direction closer to vertical direction with respect to an interface between the semiconductor lamination unit and the sapphire substrate, as compared with the intensity distribution of light being incident on the verticalized moth eye surface on the side of the semiconductor lamination unit, and that, in the angle region exceeding the critical angle, the intensity distribution of light emitted by transmission from the verticalized moth eye surface on a side of the sapphire substrate is inclined to direction closer to the vertical direction with respect to the interface, as compared with the intensity distribution of light being incident on the verticalized moth eye surface on the side of the semiconductor lamination unit, in which a reflection unit that reflects light transmitting through the verticalized moth eye surface is provided, in which a transmission moth eye surface having depression parts or projection parts whose period is smaller than twice the optical =wavelength of light emitted from the light-emitting layer is provided, and in which the light, whose intensity distribution is adjusted by reflecting on and transmitting through the verticalized moth eye surface to be inclined to the vertical direction with respect to the interface, is discharged from the transmission moth eye surface to an outer side of the element with Fresnel reflection being inhibited. Advantageous Effects of Invention

With the LED element according to the present invention, it is possible to further improve the light extraction efficiency.

### BRIEF DESCRIPTION OF DRAWINGS

FIG. 1 is a schematic sectional view of an LED element according to a first embodiment of the present invention;

FIG. 2 are explanatory views illustrating diffraction operation of light at interfaces having different indices of refraction, in which (a) illustrates the state where reflection is made at the interface, and (b) illustrates the state where transmission is made through the interface;

FIG. 3 is a graph illustrating the relationship between the angle of incident light being incident on the interface from the side of a semiconductor layer and the angle of transmission at the interface by diffraction operation, at the interface between a group III nitride semiconductor layer and a sapphire substrate, when a period of depression parts or projection parts is set as 500 nm;

FIG. 4 is a graph illustrating the relationship between the angle of incident light being incident on the interface from the side of the semiconductor layer and the angle of reflection at the interface by the diffraction operation, at the interface between the group III nitride semiconductor layer and the sapphire substrate, when the period of the depression parts or the projection parts is set as 500 nm;

FIG. 5 is an explanatory view illustrating the traveling direction of light in the element;

FIG. 6 is a partially enlarged schematic sectional view of the LED element;

FIG. 7 illustrate the sapphire substrate, in which (a) is a schematic perspective view, (b) is a schematic explanatory view taken along the A-A line, and (c) is a schematic enlarged explanatory view;

FIG. 8 is a schematic explanatory view of a plasma etching apparatus;

FIG. 9 is a flowchart illustrating an etching method of the sapphire substrate;

FIG. 10A illustrate processes of the etching method of the sapphire substrate and a mask layer, in which (a) illustrates the sapphire substrate before processing, (b) illustrates the state where the mask layer is formed on the sapphire, (c) illustrates the state where a resist film is formed on the mask layer, (d) illustrates the state where a mold is brought into contact with the resist film, and (e) illustrates the state where a pattern is formed on the resist film;

FIG. 10B illustrate processes of the etching method of the sapphire substrate and the mask layer, in which (f) illustrates the state where a residual film of the resist film is removed, (g) illustrates the state where the resist film is altered, (h) illustrates the state where the mask layer is etched by using the resist film as a mask, and (i) illustrates the state where the sapphire substrate is etched by using the mask layer as a mask;

FIG. 10C illustrate processes of the etching method of the sapphire substrate and the mask layer, in which (j) illustrates the state where the sapphire substrate is etched further by using the mask layer as a mask, (k) illustrates the state where the remaining mask layer is removed from the sapphire substrate, and (l) illustrates the state where the sapphire substrate is subjected to wet-etching;

FIG. 11 is a graph illustrating reflectivity of a reflection unit according to an example 1;

FIG. 12 is a graph illustrating the reflectivity of a reflection unit according to an example 2;

FIG. 13 is a schematic sectional view of an LED element according to a second embodiment of the present invention;

FIG. 14 is a partially enlarged schematic sectional view of the LED element;

FIG. 15 is a graph illustrating the reflectivity of a reflection unit according to an example 3; and

FIG. 16 is a graph illustrating the reflectivity of a reflection unit according to an example 4.

### DESCRIPTION OF EMBODIMENTS

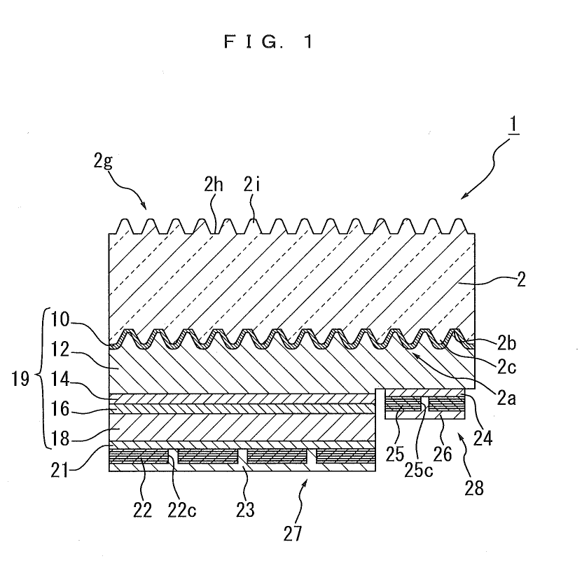

FIG. 1 is a schematic sectional view of an LED element according to a first embodiment of the present invention.

In an LED element 1, as illustrated in FIG. 1, a semiconductor lamination unit 19, formed by a group III nitride semiconductor layer, is formed on the front surface of a sapphire substrate 2. This LED element 1 is a flip-chip type, and light is mainly extracted from the back surface side of the sapphire substrate 2. The semiconductor lamination unit 19 has a buffer layer 10, an n-type GaN layer 12, a light-emitting layer 14, an electron blocking layer 16, and a p-type GaN layer 18 in this order from the sapphire substrate 2 side. A p-side electrode 27 is formed on the p-type GaN layer 18, and an n-side electrode 28 is formed on the n-type GaN layer 12.

As illustrated in FIG. 1, the buffer layer 10 is formed on the front surface of the sapphire substrate 2 and is formed by MN. According to this embodiment, the buffer layer 10 is formed by an MOCVD (Metal Organic Chemical Vapor Deposition) method, but may be formed by a sputtering method. The n-type GaN layer 12, as a first conductivity type layer, is formed on the buffer layer 10 and is formed by n-GaN. The light-emitting layer 14 is formed on the n-type GaN layer 12, formed by GalnN/GaN, and emits blue light by electron and hole injection. Here, the blue light means light whose peak wavelength is 430 nm or more and 480 nm or less, for example. According to this embodiment, the peak wavelength of light emitted from the light-emitting layer 14 is 450 nm.

The electron blocking layer 16 is formed on the light-emitting layer 14, and is foamed by p-AIGaN. The p-type GaN layer 18, as a second conductivity type layer, is formed on the electron blocking layer 16, and is formed by p-GaN. The n-type GaN layer 12 to the p-type GaN layer 18 are fowled by epitaxial growth of the group III nitride semiconductor, and projection parts 2c are periodically formed on the front surface of the sapphire substrate 2. At the beginning of growth of the group III nitride semiconductor, planarization by lateral growth is made. Incidentally, the semiconductor layer may be constituted freely as long as it includes at least the first conductivity type layer, an active layer, and the second conductivity type layer, and it emits light from the active layer by recombination of the electron and the hole when a voltage is applied to the first conductivity type layer and the second conductivity type layer.

The front surface of the sapphire substrate 2 forms a verticalized moth eye surface 2a, and the back surface of the sapphire substrate 2 forms a transmission moth eye surface 2g. On the front surface of the sapphire substrate 2, a flat part 2b and the plurality of projection parts 2c that are periodically formed on the flat part 2b are formed. The shape of each projection part 2c may be a pyramid shape such as a cone, a polygonal pyramid or the like, or may be a truncated pyramid shape, as a pyramid whose upper portion is cut off, such as a truncated cone, a truncated polygonal pyramid or the like. Each projection part 2c is designed to diffract light emitted from the light-emitting layer 14. According to this embodiment, the respective projection parts 2c, arranged periodically, allow verticalizing operation of light. Here, the verticalizing operation of light means that light intensity distribution is inclined closer to the vertical direction with respect to an interface between the sapphire substrate 2 and the semiconductor lamination unit 19, after the light is reflected and transmitted, than before the light is incident on the verticalized moth eye surface.

In addition, on the back surface of the sapphire substrate 2, a flat part 2h and a plurality of projection parts 2i that are periodically foamed on the flat part 2h are formed. The shape of each projection part 2i may be a pyramid shape such as a cone, a polygonal pyramid or the like, or may be a truncated pyramid shape, as a pyramid whose upper portion is cut off, such as a truncated cone, a truncated polygonal pyramid or the like. A period of the projection parts 2i on the transmission moth eye surface is smaller than a period of the projection parts 2c on the verticalized moth eye surface. According to this embodiment, the respective projection parts 2i, arranged periodically, inhibit Fresnel reflection at the interface with the outside.

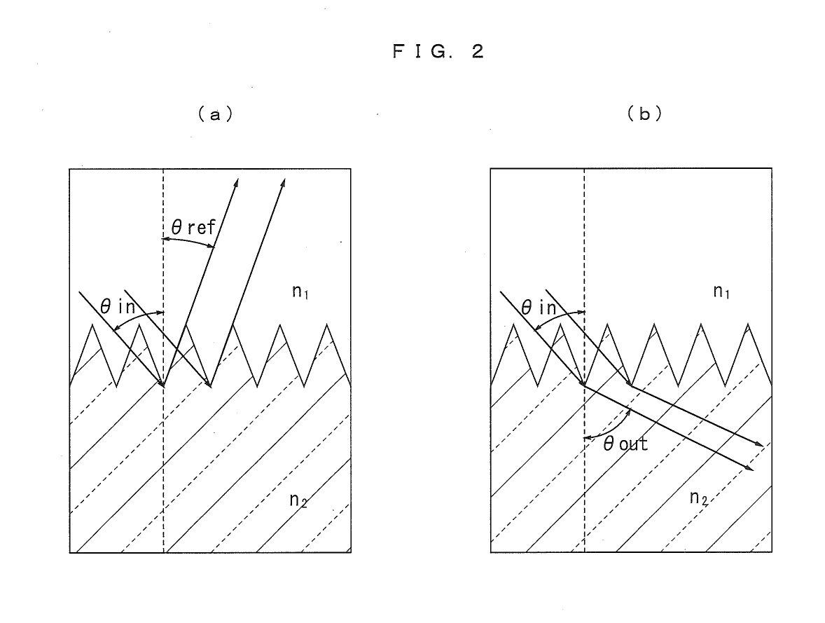

FIG. 2 are explanatory views illustrating diffraction operation of light at interfaces having different indices of refraction, in which (a) illustrates the state where reflection is made on the interface, and (b) illustrates the state where transmission is made through the interface.

Here, from the Bragg diffraction condition, the condition to be satisfied by the angle of reflection θ_{ref} with respect to the angle of incident θᵢₙ at the time when light is reflected on the interface is as follows.

d·n1·(sin θᵢₙ−sin θ_{ref})=m·λ (1)

Wherein n1 is an index of refraction of a medium on the incident side, λ is a wavelength of incident light, and m is an integer. When light is incident on the sapphire substrate 2 from the semiconductor lamination unit 19, n1 is the index of refraction of the group III nitride semiconductor. As illustrated in FIG. 2(a), light being incident on the interface is reflected at the angle of reflection θ_{ref} that satisfies the above-described expression (1).

Meanwhile, from the Bragg diffraction condition, the condition to be satisfied by the angle of transmission θₒᵤₜ with respect to the angle of incident θᵢₙ at the time when light is transmitted through the interface is as follows.

d·n1·(sin θᵢₙ−sin θ_{ref})=m·λ (2)

Wherein n2 is an index of refraction of a medium on the emission side, and m′ is an integer. When, for example, light is incident on the sapphire substrate 2 from the semiconductor lamination unit 19, n2 is the index of refraction of sapphire. As illustrated in FIG. 2(b), the light being incident on the interface is transmitted at the angle of transmission θₒᵤₜ satisfying the above-described expression (2).

For the existence of the angle of reflection θ_{ref} and the angle of transmission θₒᵤₜ satisfying the diffraction conditions of the above-described expressions (1) and (2), the period on the front surface of the sapphire substrate 2 needs to be greater than (λ/n1) and (λ/n2) as optical wavelengths in the element. Therefore, the period on the front surface of the sapphire substrate 2 is set to be greater than (λ/n1) and (λ/n2) so that diffraction light exists.

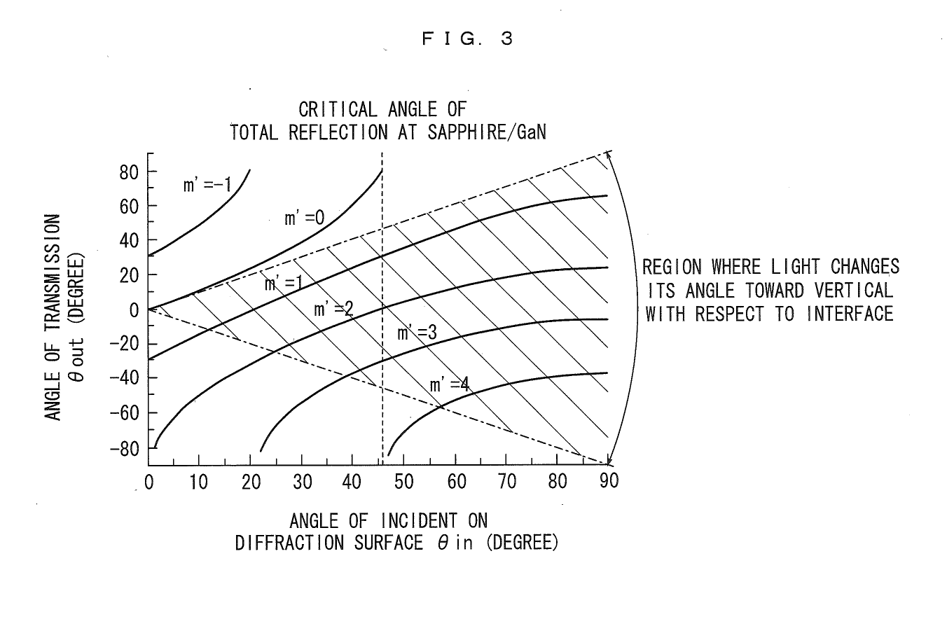

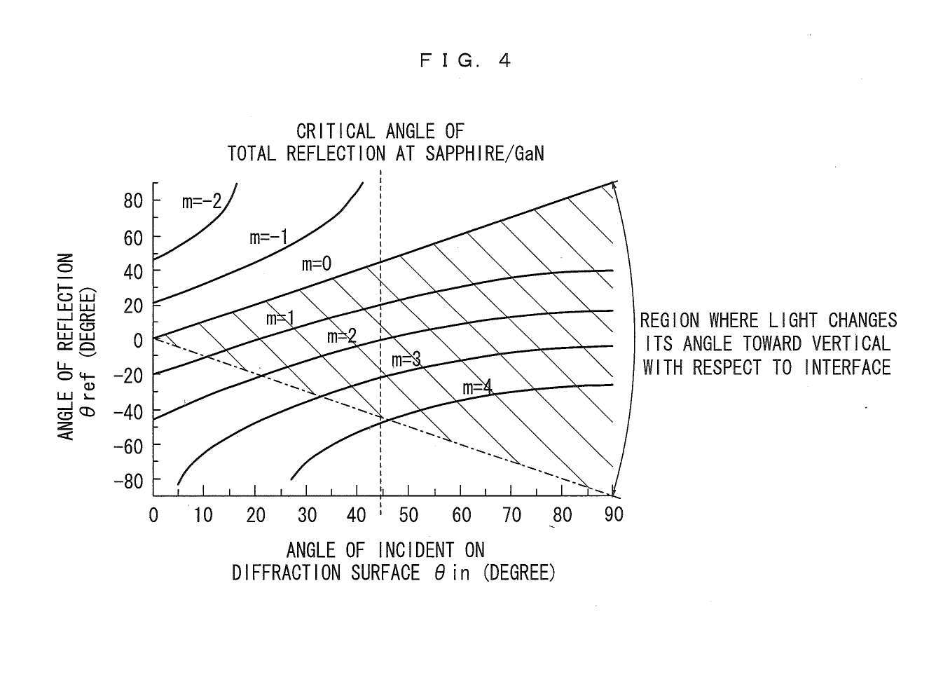

FIG. 3 is a graph illustrating the relationship between the angle of incident light being incident on the interface from the semiconductor layer side and the angle of transmission at the interface by the diffraction operation, at the interface between the group III nitride semiconductor layer and the sapphire substrate, when a period of the depression parts or the projection parts is set as 500 nm. In addition, FIG. 4 is a graph illustrating the relationship between the angle of incident light being incident on the interface from the semiconductor layer side and the angle of reflection at the interface by the diffraction operation, at the interface between the group III nitride semiconductor layer and the sapphire substrate, when the period of the depression parts or the projection parts is set as 500 nm.

As with the general flat surfaces, light being incident on the verticalized moth eye surface 2a has the critical angle of total reflection. The critical angle at the interface between the GaN-based semiconductor layer and the sapphire substrate 2 is 45.9°. In the region exceeding the critical angle, as illustrated in FIG. 3, transmission in diffraction modes of m′=1, 2, 3, and 4, satisfying the diffraction condition of the above-described expression (2), is possible. In addition, in the region exceeding the critical angle, as illustrated in FIG. 4, reflection in diffraction modes of m=1, 2, 3, and 4, satisfying the diffraction condition of the above-described expression (1), is possible. When the critical angle is 45.9°, light output exceeding the critical angle is about 70%, and light output not exceeding the critical angle is about 30%. Namely, extraction of light in the region exceeding the critical angle greatly contributes to improvement of light extraction efficiency of the LED element 1.

In the region where the angle of transmission θₒᵤₜ is smaller than the angle of incident θᵢₙ, light that transmits through the verticalized moth eye surface 2a changes its angle toward the vertical with respect to the interface between the sapphire substrate 2 and the group III nitride semiconductor layer. This region is hatched in FIG. 3. As illustrated in FIG. 3, in the region exceeding the critical angle, light that transmits through the verticalized moth eye surface 2a and that is in the diffraction modes of m′=1, 2, and 3 changes its angle toward the vertical in all angle regions. Although the light in the diffraction mode of m′=4 does not change its angle toward the vertical in a part of the angle regions, it has not so much influence as intensity of light having a greater diffraction order is relatively small, and substantially, the light also changes its angle toward the vertical in this part of the angle regions. Namely, the intensity distribution of the light transmitting through and emitting from the verticalized moth eye surface 2a on the sapphire substrate 2 side is inclined to the direction closer to the vertical with respect to the interface between the semiconductor lamination unit 19 and the sapphire substrate 2, as compared with the intensity distribution of the light being incident on the verticalized moth eye surface 2a on the semiconductor lamination unit 19 side.

In the region where the angle of reflection θ_{ref} is smaller than the angle of incident θᵢₙ, light that is reflected on the verticalized moth eye surface 2a changes its angle toward the vertical with respect to the interface between the sapphire substrate 2 and the group III nitride semiconductor layer. This region is hatched in FIG. 4. As illustrated in FIG. 4, in the region exceeding the critical angle, light that is reflected on the verticalized moth eye surface 2a and that is in the diffraction modes of m=1, 2, and 3 changes its angle toward the vertical in all angle regions. Although the light in the diffraction mode of m=4 does not change its angle toward the vertical in a part of the angle regions, it has not so much influence as intensity of light having a greater diffraction order is relatively small, and substantially, the light also changes its angle toward the vertical in this part of the angle regions. Namely, the intensity distribution of the light that is emitted, by reflection, from the verticalized moth eye surface 2a on the semiconductor lamination unit 19 side is inclined to the direction closer to the vertical with respect to the interface between the semiconductor lamination unit 19 and the sapphire substrate 2, as compared with the intensity distribution of the light being incident on the verticalized moth eye surface 2a on the semiconductor lamination unit 19 side.

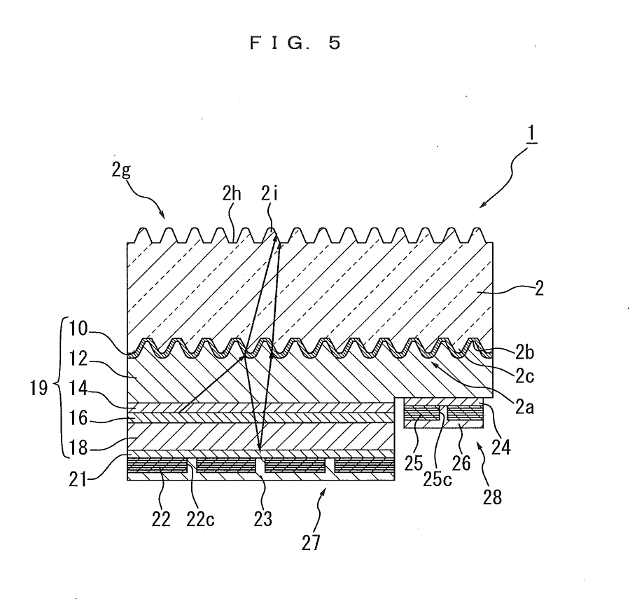

FIG. 5 is an explanatory view illustrating the traveling direction of light in the element.

As illustrated in FIG. 5, light being incident on the sapphire substrate 2 by exceeding the critical angle, among light emitted from the light-emitting layer 14, is transmitted through and reflected on the the verticalized moth eye surface 2a toward the direction closer to the vertical, as compared with the direction when it is incident on the verticalized moth eye surface 2a. Namely, light that transmits through the verticalized moth eye surface 2a is incident on the transmission moth eye surface 2g by changing its angle toward the vertical. Further, light that is reflected on the verticalized moth eye surface 2a, whose angle is changed toward the vertical, is reflected on the p-side electrode 27 and the n-side electrode 28, and thereafter, is incident on the verticalized moth eye surface 2a again. The angle of incident at this time is closer to the vertical than the angle of incident. As a result of this, light being incident on the transmission moth eye surface 2g can be directed toward the vertical.

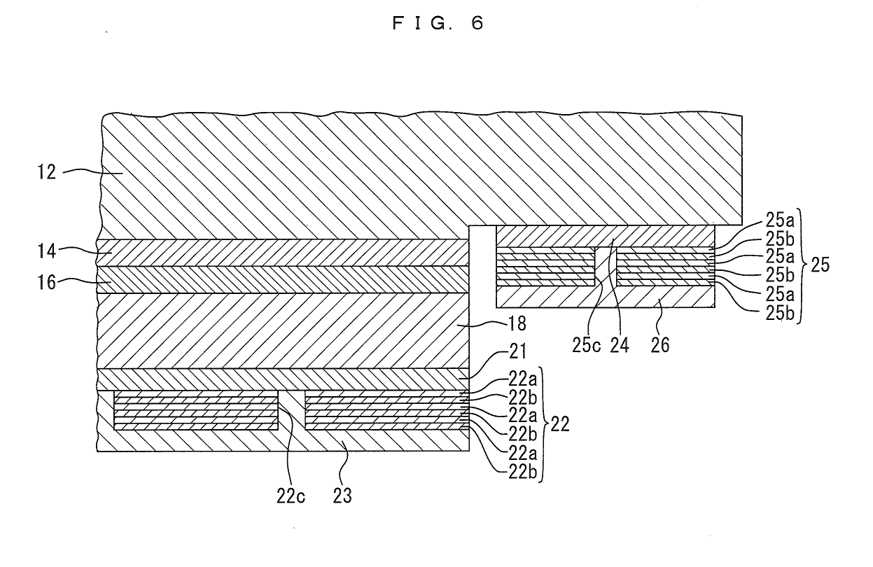

FIG. 6 is a partially enlarged schematic sectional view of the LED element.

As illustrated in FIG. 6, the p-side electrode 27 includes a diffusion electrode 21 that is formed on the p-type GaN layer 18, a dielectric multilayer film 22 that is formed on the predetermined region on the diffusion electrode 21, and a metal electrode 23 that is formed on the dielectric multilayer film 22. The diffusion electrode 21 is formed entirely on the p-type GaN layer 18, and is formed by a transparent material such as ITO (Indium Tin Oxide), for example. The dielectric multilayer film 22 is formed by repeating a plurality of pairs of a first material 22a and a second material 22b, having different indices of refraction. For example, the dielectric multilayer film 22 may have five pairs of the first material 22a of ZrO₂ (index of refraction: 2.18) and the second material 22b of SiO₂ (index of refraction: 1.46). It should be noted that materials other than ZrO₂ and SiO₂ may be used to form the dielectric multilayer film 22, and AN (index of refraction: 2.18), Nb₂O₃ (index of refraction: 2.4), Ta₂O₃ (index of refraction: 2.35) or the like may be used, for example. The metal electrode 23 covers the dielectric multilayer film 22, and is formed by a metal material such as Al, for example. The metal electrode 23 is electrically connected to the diffusion electrode 21 through a via hole 22a formed in the dielectric multilayer film 22.

As illustrated in FIG. 6, the n-side electrode 28 is formed on the n-type GaN layer 12 exposed after etching the p-type GaN layer 18 to the n-type GaN layer 12. The n-side electrode 28 includes a diffusion electrode 24 that is formed on the n-type GaN layer 12, a dielectric multilayer film 25 that is formed on the predetermined region on the diffusion electrode 24, and a metal electrode 26 that is formed on the dielectric multilayer film 25. The diffusion electrode 24 is formed entirely on the n-type GaN layer 12, and is formed by a transparent material such as ITO (Indium Tin Oxide), for example. The dielectric multilayer film 25 is formed by repeating a plurality of pairs of a first material 25a and a second material 25b, having different indices of refraction. For example, the dielectric multilayer film 25 may have five pairs of the first material 25a of ZrO₂ (index of refraction: 2.18) and the second material 25b of SiO₂ (index of refraction: 1.46). It should be noted that materials other than ZrO₂ and SiO₂ may be used to form the dielectric multilayer film 25, and MN (index of refraction: 2.18), Nb₂O₃ (index of refraction: 2.4), Ta₂O₃ (index of refraction: 2.35) or the like may be used, for example. The metal electrode 26 covers the dielectric multilayer film 25, and is formed by a metal material such as Al, for example. The metal electrode 26 is electrically connected to the diffusion electrode 24 through a via hole 25a formed in the dielectric multilayer film 25.

In this LED element 1, the p-side electrode 27 and the n-side electrode 28 foam a reflection unit. Reflectivity of the p-side electrode 27 and the n-side electrode 28 becomes higher as the angle comes closer to the vertical. Light that is reflected on the verticalized moth eye surface 2a of the sapphire substrate 2 and changes its angle toward the vertical with respect to the interface, as well as light emitted from the light-emitting layer 14 and being incident thereon directly, is incident on the reflection unit. Namely, the intensity distribution of light being incident on the reflection unit is inclined to the direction closer to the vertical, as compared with the case where the front surface of the sapphire substrate 2 forms the flat surface.

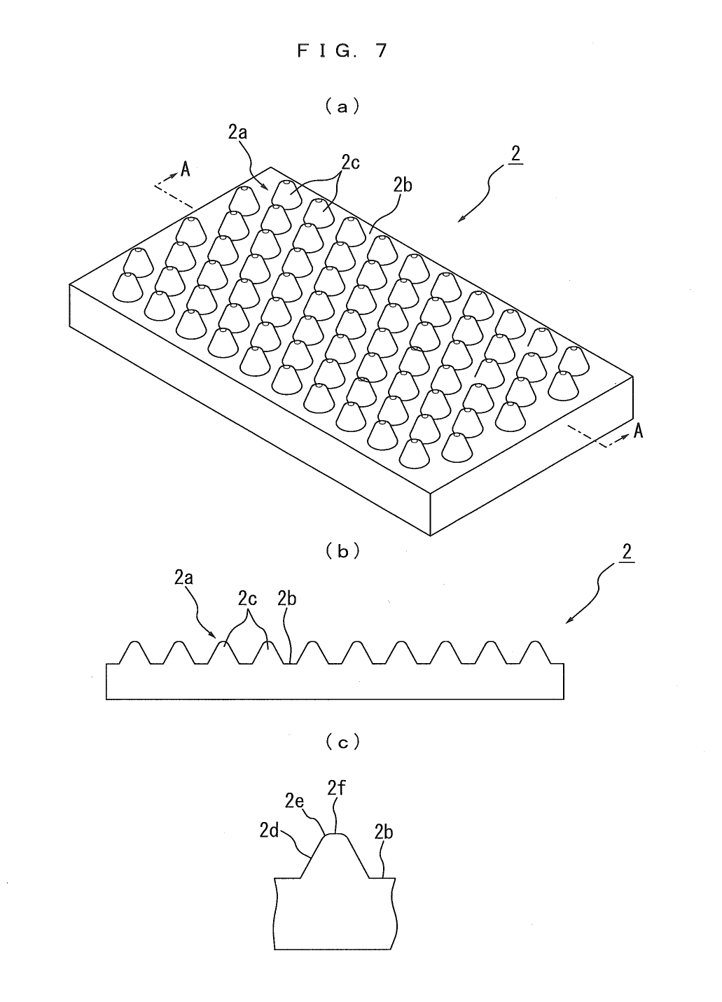

Next, the sapphire substrate 2 will be described in detail with reference to FIGS. 7. FIG. 7 illustrate the sapphire substrate, in which (a) is a schematic perspective view, (b) is a schematic explanatory view taken along with the A-A line, and (c) is a schematic enlarged explanatory view.

In the verticalized moth eye surface 2a, as illustrated in FIG. 7(a), the projection parts 2c are found to align at points of intersection of a virtual triangle lattice with the predetermined period, so that the centers of the respective projection parts 2c are positioned at vertices of regular triangles in planar view. The period of the respective projection parts 2c is greater than an optical wavelength of light emitted from the light-emitting layer 14, and is smaller than coherent length of the light. It should be noted that the period in this case means the distance between the adjacent projection parts 2c at the position having the peak height. Further, the optical wavelength means the value obtained by dividing the actual wavelength by the index of refraction. Furthermore, the coherent length corresponds to the distance until the coherence eliminates as periodic vibrations of the waves are cancelled due to difference in the respective wavelengths in a photon group of the predetermined spectrum width. Supposing that the wavelength of light is λ and the half-value width of the light is Δλ, coherent length 1c roughly has the relationship of 1c=(λ²/Δλ). When the period of the respective projection parts 2c is one or more time greater than the optical wavelength, the diffraction operation gradually and effectively starts to act on the incident light having the angle of the critical angle or more, and when the period is two or more times greater than the optical wavelength of the light emitted from the light-emitting layer 14, the number of transmission modes and reflection modes increases sufficiently, which is favorable. In addition, it is favorable that the period of the respective projection parts 2c is less than half the coherent length of the light emitted from the light-emitting layer 14.

According to this embodiment, the period of the respective projection parts 2c is 460 nm. The wavelength of light emitted from the light-emitting layer 14 is 450 nm, and the index of refraction of the group III nitride semiconductor layer is 2.4, and therefore its optical wavelength is 187.5 nm. Further, the half-value width of the light emitted from the light-emitting layer 14 is 27 nm, and hence the coherent length of the light is 7837 nm. Namely, the period of the verticalized moth eye surface 2a is greater than twice the optical wavelength of the light-emitting layer 14, and less than half the coherent length.

According to this embodiment, as illustrated in FIG. 7(c), each projection part 2c on the verticalized moth eye surface 2a includes a side surface 2d that extends upward from the flat part 2b, a bent portion 2e that bends and extends from the upper end of the side surface 2d toward the center side of the projection part 2c, and a flat top surface 2f that is formed continuously from the bent portion 2e. As will be described later, before the formation of the bent portion 2e, the projection part 2c, on which a corner is formed at a portion associating the side surface 2d and the top surface 2f, is wet-etched and rounded, and thus the bent portion 2e is formed. The wet-etching may be made until the flat top surface 2f eliminates and the entire upper side of the projection part 2c becomes the bent portion 2e. Specifically, according to this embodiment, the diameter of the base end portion of each projection part 2c is 380 nm, and its height is 350 nm. In the verticalized moth eye surface 2a of the sapphire substrate 2, the flat part 2b is provided at the position where the projection parts 2c are not provided, thus facilitating the lateral growth of the semiconductor.

In the transmission moth eye surface 2g at the back surface of the sapphire substrate 2, the projection parts 2i are formed to align at points of intersection of a virtual triangle lattice with the predetermined period, so that the centers of the respective projection parts 2i are positioned at vertices of regular triangles in planar view. The period of the respective projection parts 2i is smaller than an optical wavelength of light emitted from the light-emitting layer 14. Namely, the Fresnel reflection is inhibited at the transmission moth eye surface 2g. According to this embodiment, the period of the respective projection parts 2i is 300 nm. The wavelength of light emitted from the light-emitting layer 14 is 450 nm, and the index of refraction of sapphire is 1.78, and therefore its optical wavelength is 252.8 nm Namely, the period of the transmission moth eye surface 2g is less than twice the optical wavelength of the light-emitting layer 14. It should be noted that, when the period on the moth eye surface is equal to or less than twice the optical wavelength, the Fresnel reflection at the interface can be inhibited. When the period on the moth eye surface 2g comes closer from two times to one time, inhibitive action of the Fresnel reflection increases. When the outside of the sapphire substrate 2 is resin or air, and when the period of the transmission moth eye surface 2g is equal to or less than 1.25 times the optical wavelength, it is possible to obtain the inhibitive action of the Fresnel reflection that is almost equal to that of one time or less.

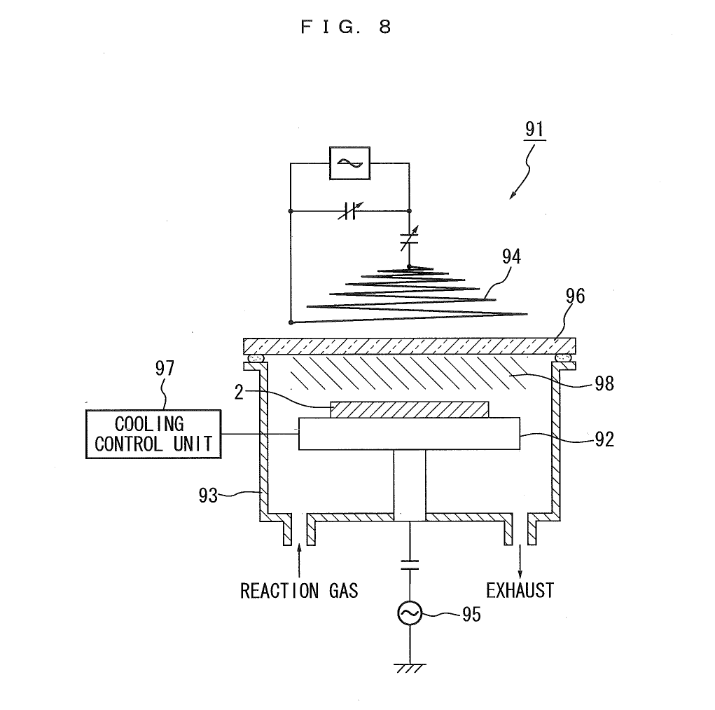

Now, a manufacturing method of the sapphire substrate 2 for the LED element 1 will be explained with reference to FIG. 8 to FIG. 10C. FIG. 8 is a schematic explanatory view of a plasma etching apparatus for processing a sapphire substrate.

As illustrated in FIG. 8, a plasma etching apparatus 91 is an inductive coupling (ICP) type, and includes a flat plate-shaped substrate holding table 92 that holds the sapphire substrate 2, a container 93 that receives the substrate holding table 92, a coil 94 that is provided above the container 93 via a quartz plate 96, and a power supply 95 that is connected to the substrate holding table 92. The coil 94 has a three-dimensional spiral shape and supplies high frequency power from the center of the coil. The end of the outer periphery of the coil is grounded. The sapphire substrate 2 to be etched is placed on the substrate holding table 92 directly or by a carrier tray. The substrate holding table 92 has a cooling mechanism for cooling the sapphire substrate 2 in its inside, and is controlled by a cooling control unit 97. The container 93 has a supply port that enables supply of various gases, such as an O₂ gas, an Ar gas and the like.

When the etching is made by this plasma etching apparatus 1, the sapphire substrate 2 is placed on the substrate holding table 92 and then, air inside the container 93 is discharged to attain a decompressed state. The predetermined processing gas is supplied into the container 93, and gas pressure inside the container 93 is adjusted. Thereafter, high-output and high-frequency power is supplied to the coil 94 and the substrate holding table 92 for the predetermined period of time, and plasma 98 of a reaction gas is formed. This plasma 98 is used for etching the sapphire substrate 2.

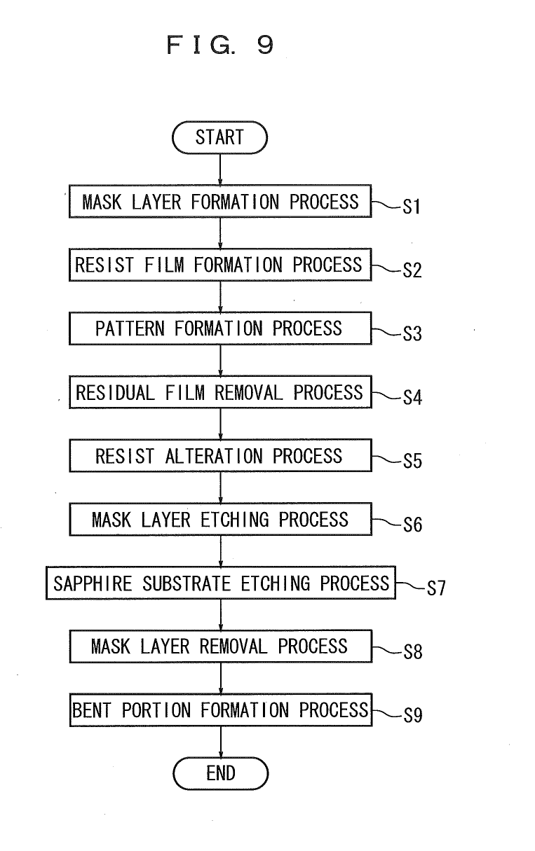

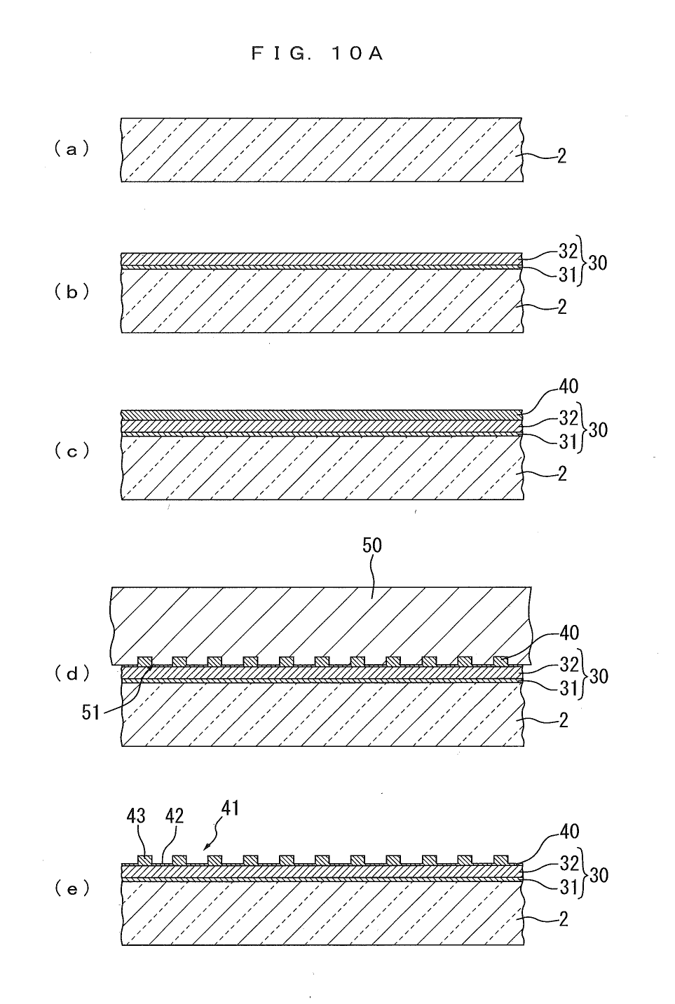

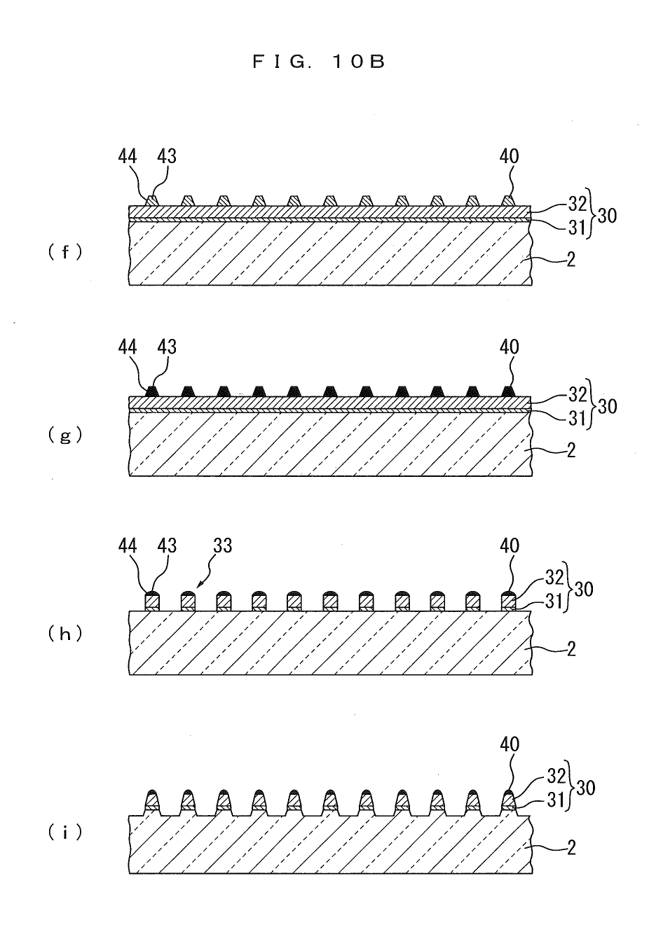

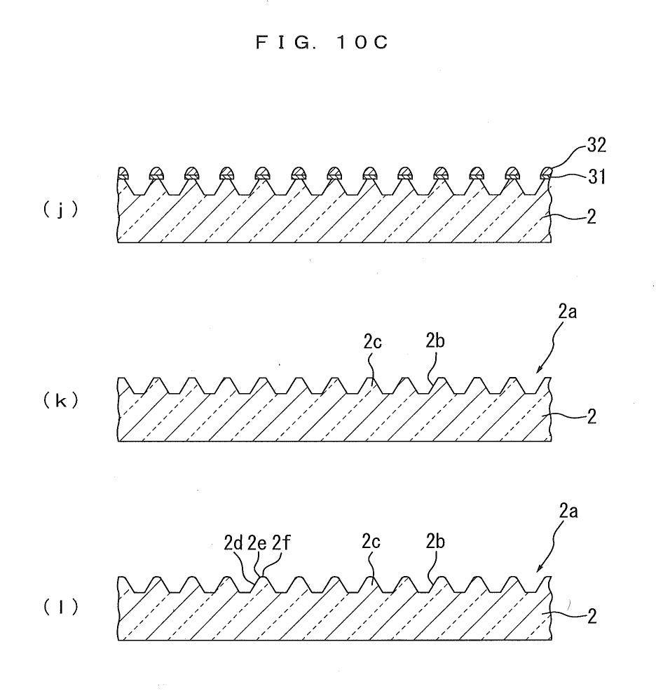

Next, an etching method by using the plasma etching apparatus 1 will be explained with reference to FIG. 9, FIG. 10A, FIG. 10B and FIG. 10C.

FIG. 9 is a flowchart illustrating the etching method. As illustrated in FIG. 9, the etching method according to this embodiment includes a mask layer formation process S1, a resist film formation process S2, a pattern formation process S3, a residual film removal process S4, a resist alteration process S5, a mask layer etching process S6, a sapphire substrate etching process S7, a mask layer removal process S8, and a bent portion formation process S9.

FIG. 10A illustrate processes of the etching method of the sapphire substrate and the mask layer, in which (a) illustrates the sapphire substrate before processing, (b) illustrates the state where the mask layer is formed on the sapphire substrate, (c) illustrates the state where a resist film is formed on the mask layer, (d) illustrates the state where a mold is brought into contact with the resist film, and (e) illustrates the state where a pattern is formed on the resist film.

FIG. 10B illustrate processes of the etching method of the sapphire substrate and the mask layer, in which (f) illustrates the state where a residual film of the resist film is removed, (g) illustrates the state where the resist film is altered, (h) illustrates the state where the mask layer is etched by using the resist film as a mask, and (i) illustrates the state where the sapphire substrate is etched by using the mask layer as a mask. It should be noted that the resist film after the alteration is filled in with black in the drawings.

FIG. 10C illustrate processes of the etching method of the sapphire substrate and the mask layer, in which (j) illustrates the state where the sapphire substrate is etched further by using the mask layer as a mask, (k) illustrates the state where the remaining mask layer is removed from the sapphire substrate, and (l) illustrates the state where the sapphire substrate is subjected to the wet-etching

First, as illustrated in FIG. 10A(a), the sapphire substrate 2 before processing is provided. Prior to the etching, the sapphire substrate 2 is cleaned by the predetermined cleaning liquid. According to this embodiment, the sapphire substrate 2 is a substrate formed by sapphire.

Then, as illustrated in FIG. 10A(b), a mask layer 30 is formed on the sapphire substrate 2 (mask layer formation process: S1). According to this embodiment, the mask layer 30 includes a SiO₂ layer 31 on the sapphire substrate 2, and a Ni layer 32 on the SiO₂ layer 31. The thickness of each of the layers 31 and 112 may be freely set, but the SiO₂ layer may be set to have the thickness of 1 nm or more and 100 nm or less, and the Ni layer 32 may be set to have the thickness of 1 nm or more and 100 nm or less, for example. Incidentally, the mask layer 30 may have a single layer. The mask layer 30 is formed by the sputtering method, a vacuum deposition method, a CVD method, or the like.

Next, as illustrated in FIG. 10A(c), the resist film 40 is formed on the mask layer 30 (resist film formation process: S2). According to this embodiment, the resist film 40 is formed by thermoplastic resin, and is formed by a spin coating method to have the uniform thickness. The resist film 40 is formed by, for example, epoxy-based resin, and its thickness is 100 nm or more and 300 nm or less, for example. Incidentally, it is also possible to use photosetting resin as the resist film 40.

The resist film 40, together with the sapphire substrate 2, is heated and softened and, as illustrated in FIG. 10A(d), the resist film 40 is pressed by a mold 50. A projection-and-depression structure 51 is formed on the contact surface of the mold 50, and the resist film 40 is deformed along the projection-and-depression structure 51.

Thereafter, the resist film 40, while being pressed, is cooled and hardened, together with the sapphire substrate 2. The mold 50 is then separated from the resist film 40 and, as illustrated in FIG. 10A(e), a projection-and-depression structure 41 is transferred to the resist film 40 (pattern formation process: S3). Here, the period of the projection-and-depression structure 41 is 1 μm or less. According to this embodiment, the period of the projection-and-depression structure 41 is 460 nm. Further, according to this embodiment, the diameter of a projection part 43 of the projection-and-depression structure 41 is 100 nm or more and 300 nm or less, and is 230 nm, for example. Furthermore, the height of the projection part 43 is 100 nm or more and 300 nm or less, and is 250 nm, for example. In this state, a residual film 42 is formed on a depression part of the resist film 40.

The sapphire substrate 2, on which the resist film 40 is formed as described above, is mounted on the substrate holding table 92 of the plasma etching apparatus 1. Then, the residual film 42 is removed by plasma ashing, for example, and the mask layer 30, as the material to be processed, is exposed, as illustrated in FIG. 10B(f) (residual film removal process: S4). According to this embodiment, the O₂ gas is used as the processing gas for the plasma ashing. At this time, the projection part 43 of the resist film 40 is subjected to the influence of the ashing, and a side surface 44 of the projection part 43 is tilted by the predetermined angle, not being vertical to the front surface of the mask layer 30.

Then, as illustrated in FIG. 10B(g), the resist film 40 is exposed to the plasma under an alteration condition, so as to alter the resist film 40 and increase etch selectivity (resist alteration process: S5). According to this embodiment, the Ar gas is used as the processing gas for altering the resist film 40. Further, with regard to the alteration condition according to this embodiment, bias output of the power supply 95 for guiding the plasma to the sapphire substrate 2 side is set to be lower than that of a later-described etching condition.

Then, the resist film 40, having the high etch selectivity after being exposed to the plasma under the etching condition, is used as a mask to etch the mask layer 30 as the material to be processed (mask layer etching process: S6). According to this embodiment, the Ar gas is used as the processing gas for etching the resist film 40. Thereby, as illustrated in FIG. 10B(h), a pattern 33 is formed on the mask layer 30.

With regard to the alteration condition and the etching condition, it is possible to change the processing gas, antenna output, the bias output and the like as appropriate, but it is preferable to change the bias output by using the same processing gas, as in this embodiment. Specifically, with regard to the alteration condition, the Ar gas is set as the processing gas, the antenna output of the coil 94 is set as 350 W, and the bias output of the power supply 95 is set as 50 W, as a result of which the hardening of the resist film 40 is observed. Further, with regard to the etching condition, the Ar gas is set as the processing gas, the antenna output of the coil 94 is set as 350 W, and the bias output of the power supply 95 is set as 100 W, as a result of which the etching of the mask layer 30 is observed. It should be noted that the hardening of the resist is possible when the antenna output is lowered and a gas flow rate is reduced, as well as when the bias output is lowered, with respect to the etching condition.

Next, as illustrated in FIG. 10B(i), the sapphire substrate 2 is etched by using the mask layer 30 as a mask (sapphire substrate etching process: S7). According to this embodiment, the etching is made while the resist film 40 remains on the mask layer 30. Further, plasma etching is made by using a chlorine-based gas, such as a BCl₃ gas, as the processing gas.

When the etching progresses, as illustrated in FIG. 10C(j), the verticalized moth eye surface 2a is formed on the sapphire substrate 2. According to this embodiment, the height of the projection-and-depression structure on the verticalized moth eye surface 2a is 350 nm. Incidentally, the height of the projection-and-depression structure may be increased to be greater than 350 nm. When the height of the projection-and-depression structure is relatively small, such as 300 nm, for example, the etching may be finished while the remaining resist film 40 exists, as illustrated in FIG. 10B(i).

According to this embodiment, side etching is facilitated by the SiO₂ layer 31 of the mask layer 30, and the side surface 2d of the projection part 2c on the verticalized moth eye surface 2a is tilted. Further, a tilt angle of the side surface 43 of the resist film 40 can also control the state of the side etching. It should be noted that, when the mask layer 30 is made as a single layer of the Ni layer 32, the side surface 2d of the projection part 2c can be made almost vertical to the main surface.

Thereafter, as illustrated in FIG. 10B(k), the predetermined stripping liquid is used to remove the mask layer 30 remaining on the sapphire substrate 2 (mask layer removal process: S8). According to this embodiment, high-temperature nitric acid is used to remove the Ni layer 32, and then, hydrofluoric acid is used to remove the SiO₂ layer 31. When the resist film 40 remains on the mask layer 30, it can be removed together with the Ni layer 32 by the high-temperature nitric acid. However, when the remaining amount of the resist film 40 is large, it is preferable to remove the resist film 40 by O₂ ashing in advance.

Then, as illustrated in FIG. 10B(1), the corner on the projection part 2c is removed by the wet-etching, so as to form the bent portion (bent portion formation process: S9). Although the etching solution can be freely selected, it is possible to use the so-called “hot phosphoric acid” as phosphoric acid aqueous solution that is heated to about 170° C., for example. Incidentally, this bent portion formation process can be omitted as appropriate. After the above-described processes, the sapphire substrate 2 having the projection-and-depression structure on its front surface is manufactured.

According to this etching method of the sapphire substrate 2, the alteration of the resist film 40 is made by exposing itself to the plasma, and thus the etching selectivity of the mask layer 30 and the resist film 40 can be improved. This makes it possible to facilitate the processing of the fine and deep pattern on the mask layer 30, and to form the mask layer 30, having the fine pattern, with enough thickness.

Further, the plasma etching apparatus 1 can alter the resist film 40 and etch the mask layer 30 in a continuous manner, without significantly increasing man-hour. According to this embodiment, the alteration of the resist film 40 and the etching of the mask layer 30 are made by changing the bias output of the power supply 95, which makes it possible to increase the selectivity of the resist film 40 with ease.

Furthermore, as the mask layer 30, having the enough thickness, is used as the mask to etch the sapphire substrate 2, the processing of the fine and deep pattern on the sapphire substrate 2 is facilitated. Especially, according to the etching method of this embodiment, it is possible to form the projection-and-depression structure having the period of 1 μm or less and the depth of 300 nm or more on the sapphire substrate, which has been impossible with the conventional etching method that forms the resist film on the substrate on which the mask layer is formed and that uses the resist film for etching the mask layer. Especially, the etching method according to this embodiment is suitable for forming the projection-and-depression structure having the period of 1 μm or less and the depth of 500 nm or more.

The nano-scaled periodic projection-and-depression structure is referred to as the moth eye. When sapphire is subjected to this processing of the moth eye, the processing is possible only to the depth of about 200 nm, as sapphire is a material that is difficult to grind. In some cases, however, difference in level of about 200 nm is not enough for the moth eye. It is possible to say that the etching method according to this embodiment solves this new problem at the time when the sapphire substrate is subjected to the moth eye processing.

It is needless to say that, although the mask layer 30 formed by SiO₂/Ni is presented as the material to be processed, the mask layer 30 may be a single layer of Ni or may be formed by other materials. What is required is to alter the resist and increase the etch selectivity of the mask layer 30 and the resist film 40.

In addition, the case of setting the alteration condition and the etching condition by changing the bias output of the plasma etching apparatus 1 is presented, but the setting may be made by changing the antenna output, the gas flow rate, or the processing gas, for example. What is required for the alteration condition is that the resist alters when being exposed to the plasma so as to increase the etch selectivity.

In addition, the mask layer 30 including the Ni layer 32 is presented, but it is needless to say that the present invention can be applied to the etching of other materials. The etching method of the sapphire substrate according to this embodiment can be applied to a substrate of SiC, Si, GaAs, GaN, InP, ZnO or the like.

The semiconductor lamination unit 19 formed by the group III nitride semiconductor is formed by the epitaxial growth on thus-manufactured verticalized moth eye surface 2a of the sapphire substrate 2 by using the lateral growth (semiconductor formation process), on which the p-side electrode 27 and the n-side electrode 28 are formed (electrode formation process). Thereafter, the projection parts 2i are formed on the back surface of the sapphire substrate 2 according to the same processes as those used for the verticalized moth eye surface 2a on the front surface, which is diced and divided into a plurality of the LED elements 1. Thus, the LED element 1 is manufactured.

Thus-formed LED element 1 is provided with the verticalized moth eye surface 2a, therefore light being incident on the interface between the sapphire substrate 2 and the group III nitride semiconductor layer, by exceeding the critical angle of total reflection, can be directed toward the vertical with respect to the interface. In addition, as the transmission moth eye surface 2g that inhibits the Fresnel reflection is provided, it is possible to smoothly extract light, whose angle is directed toward the vertical, to the outside of the element, at the interface between the sapphire substrate 2 and the outside of the element. Although the front surface and the back surface of the sapphire substrate 2 are both processed to have the projections and the depressions, both have different functions of the verticalizing function and the Fresnel reflection inhibiting function, and the light extraction efficiency can be dramatically improved due to synergy between these functions.

Further, the distance of light, emitted from the light-emitting layer 14, until reaching the back surface of the sapphire substrate 2, can be reduced substantially, and the absorption of light in the element can be suppressed. The LED element has such a problem that light is absorbed in the element as light in the angle region exceeding the critical angle of the interface propagates laterally. However, light in the angle region exceeding the critical angle is directed toward the vertical at the verticalized moth eye surface 2a, and the Fresnel reflection of the light that is directed toward the vertical is inhibited at the transmission moth eye surface 2g, and thus the light absorbed in the element can be reduced drastically.

Further, as the period of the projection parts 2c is small in the LED element 1 according to this embodiment, the number of the projection parts 2c per unit area is increased. When the projection part 2c is more than twice the coherent length, existence of the corner, as a starting point of dislocation, in the projection part 2c has not so much influence on the light emitting efficiency as dislocation density is small. When the period of the projection parts 2c is smaller than the coherent length, however, the dislocation density in the buffer layer 10 of the semiconductor lamination unit 19 increases, and the reduction in the light emitting efficiency becomes remarkable. This tendency becomes more remarkable when the period becomes 1 urn or less. It should be noted that the reduction in the light emitting efficiency is caused irrespective of the manufacturing method of the buffer layer 10, and is caused even when it is manufactured by the MOCVD method or by the sputtering method. According to this embodiment, the corner, as the starting point of the dislocation, does not exist on the upper side of each projection part 2c, and the dislocation is not caused from this corner as the starting point, at the time of forming the buffer layer 10. As a result of this, dislocation density of crystal of the light-emitting layer 14 is relatively small, and the light emitting efficiency is not lost due to the formation of the projection parts 2c on the verticalized moth eye surface 2a.

Here, the present inventors have found out that, by using the combination of the dielectric multilayer films 22 and 25 and the metal layers 23 and 26 as the p-side electrode 27 and the n-side electrode 28, the light extraction efficiency of the LED element 1 increases substantially. Namely, when the dielectric multilayer films 22 and 25 and the metal layers 23 and 26 are combined, the reflectivity increases as the angle comes closer to the vertical with respect to the interface, which attains favorable reflection condition for light that is directed toward the vertical with respect to the interface.

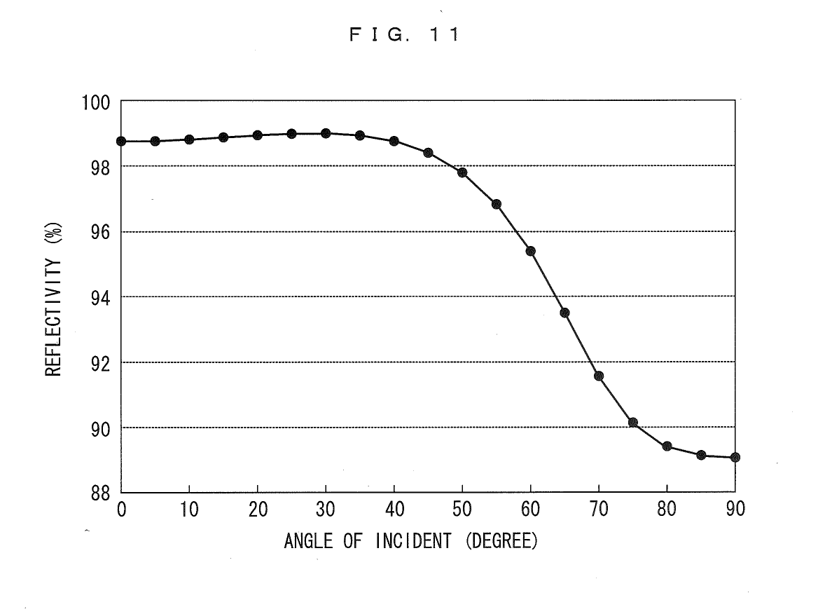

FIG. 11 is a graph illustrating the reflectivity of the reflection unit according to an example 1. According to the example 1, five pairs of ZrO₂ and SiO₂ are combined to form the dielectric multilayer film on ITO, and the Al layer is faulted to overlap the dielectric multilayer film. As illustrated in FIG. 11, the reflectivity of 98% or more is realized in the angle region where the angle of incident is from 0 degree to 45 degrees. Further, the reflectivity of 90% or more is realized in the angle region where the angle of incident is from 0 degree to 75 degrees. Thus, the combination of the dielectric multilayer film and the metal layer is favorable as the reflection condition for light that is directed toward the vertical with respect to the interface.

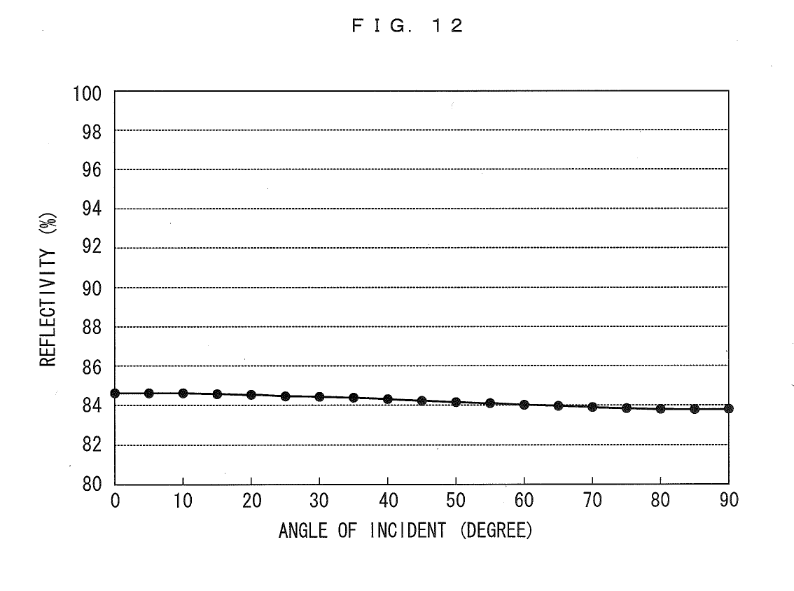

FIG. 12 is a graph illustrating the reflectivity of a reflection unit according to an example 2. According to the example 2, only the Al layer is formed on ITO. As illustrated in FIG. 12, the reflectivity shows 84% almost constantly, irrespective of the angle of incident. Thus, the reflection unit may be a single layer of metal, such as the Al layer.

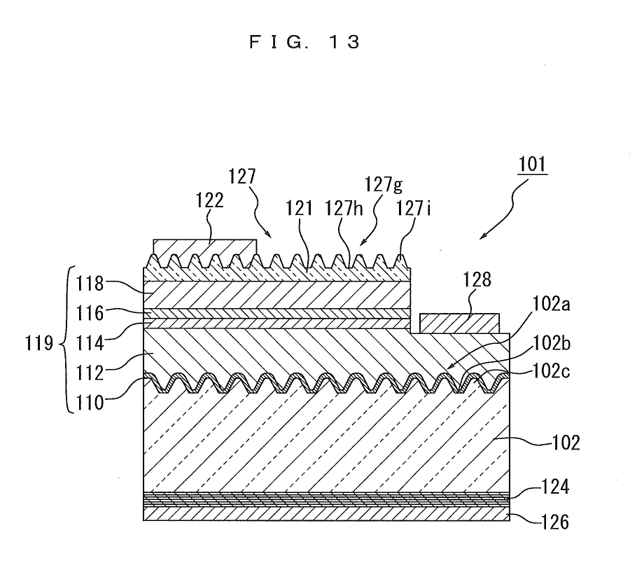

FIG. 13 is a schematic sectional view of an LED element according to a second embodiment of the present invention.

In this LED element 101, as illustrated in FIG. 13, a semiconductor lamination unit 119 formed by a group III nitride semiconductor layer is formed on the front surface of a sapphire substrate 102. This LED element 101 is a face-up type, and light is mainly extracted from the side opposite to the sapphire substrate 102. The semiconductor lamination unit 119 has a buffer layer 110, an n-type GaN layer 112, a light-emitting layer 114, an electron blocking layer 116, and a p-type GaN layer 118 in this order from the sapphire substrate 102 side. A p-side electrode 127 is formed on the p-type GaN layer 118, and an n-side electrode 128 is fanned on the n-type GaN layer 112.

As illustrated in FIG. 13, the buffer layer 110 is formed on the front surface of the sapphire substrate 102, and is formed by AN. The n-type GaN layer 112 is formed on the buffer layer 110, and is formed by n-GaN. The light-emitting layer 114 is formed on the n-type GaN layer 112, and is formed by GalnN/GaN. According to this embodiment, a peak wavelength of light emitted from the light-emitting layer 114 is 450 nm.

The electron blocking layer 116 is foamed on the light-emitting layer 114, and is formed by p-AIGaN. The p-type GaN layer 118 is formed on the electron blocking layer 116, and is formed by p-GaN. The n-type GaN layer 112 to the p-type GaN layer 118 are formed by epitaxial growth of the group III nitride semiconductor, and projection parts 102c are periodically formed on the front surface of the sapphire substrate 102. However, at the beginning of growth of the group III nitride semiconductor, planarization by lateral growth is made. Incidentally, the semiconductor layer may be constituted freely as long as it includes at least a first conductivity type layer, an active layer, and a second conductivity type layer, and it emits light from the active layer by recombination of an electron and a hole when a voltage is applied to the first conductivity type layer and the second conductivity type layer.

According to this embodiment, the front surface of the sapphire substrate 102 forms a verticalized moth eye surface 102a, and the p-side electrode 127 forms a transmission moth eye surface 127g. On the front surface of the sapphire substrate 102, a flat part 102b and the plurality of projection parts 102c that are periodically formed on the flat part 102b are formed. The shape of each projection part 102c may be a pyramid shape such as a cone, a polygonal pyramid or the like, or may be a truncated pyramid shape, as a pyramid whose upper portion is cut off, such as a truncated cone, a truncated polygonal pyramid or the like. Each projection part 102c is designed to diffract light emitted from the light-emitting layer 114. According to this embodiment, the respective projection parts 102c arranged periodically allow verticalizing operation of light.

The p-side electrode 127 includes a diffusion electrode 121 that is formed on the p-type GaN layer 118, and a pad electrode 122 that is formed on a part of the diffusion electrode 121. The diffusion electrode 121 is formed entirely on the p-type GaN layer 118, and is formed by a transparent material such as ITO (Indium Tin Oxide), for example. The pad electrode 122 is formed by a metal material such as Al, for example. On the front surface of the diffusion electrode 121, a flat part 127h and a plurality of projection parts 127i that are periodically formed on the flat part 127h are formed. The shape of each projection part 127i may be a pyramid shape such as a cone, a polygonal pyramid or the like, or may be a truncated pyramid shape, as a pyramid whose upper portion is cut off, such as a truncated cone, a truncated polygonal pyramid or the like. A period of the projection parts 127i on the transmission moth eye surface is less than twice an optical wavelength of the light-emitting layer 114. According to this embodiment, the respective projection parts 127i arranged periodically inhibit the Fresnel reflection at the interface with the outside.

The n-side electrode 128 is formed on the n-type GaN layer 112 exposed after etching the p-type GaN layer 118 to the n-type GaN layer 112. The n-side electrode 128 is formed on the n-type GaN layer 12, and is formed by a metal material such as Al, for example.

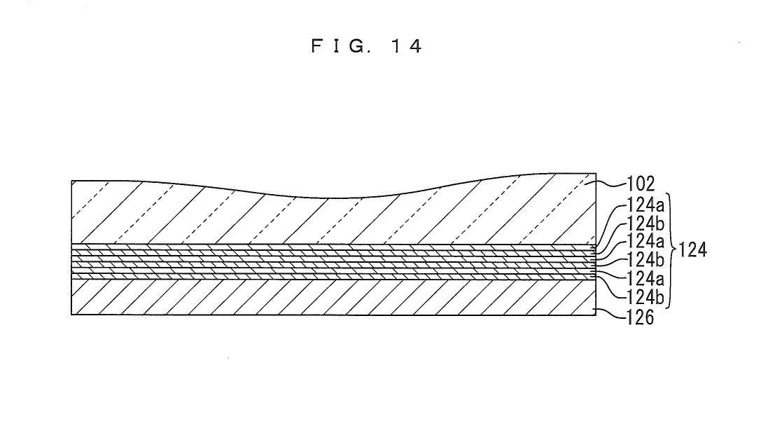

FIG. 14 is a partially enlarged schematic sectional view of the LED element.

As illustrated in FIG. 14, a dielectric multilayer film 124 is formed on the back surface side of the sapphire substrate 102. The dielectric multilayer film 124 is covered by an Al layer 126 as a metal layer. In this light emitting element 101, the dielectric multilayer film 124 and the Al layer 126 form a reflection unit, and light emitted from the light-emitting layer 114 and transmitted through the verticalized moth eye surface 102a by the diffraction operation is reflected on the reflection unit. The light transmitted by the diffraction operation is incident on the diffraction surface 102a again, and transmits through the diffraction surface 102a by using the diffraction operation again, as a result of which the light can be extracted to the outside of the element in a plurality of modes.

Thus-formed LED element 101 is provided with the verticalized moth eye surface 102a and therefore, light that is incident by exceeding the critical angle of total reflection can be directed toward the vertical, at the interface between the sapphire substrate 102 and the group III nitride semiconductor layer. In addition, as the transmission moth eye surface 127g is provided, it is possible to inhibit the Fresnel reflection of the light directed toward the vertical at the interface between the sapphire substrate 102 and the outside of the element. Thereby, it is possible to dramatically improve the light extraction efficiency.

Further, the distance of light, emitted from the light-emitting layer 114, until reaching the front surface of the p-side electrode 127, can be reduced substantially, and the absorption of light in the element can be suppressed. The LED element has such a problem that light is absorbed in the element as light in the angle region exceeding the critical angle of the interface propagates laterally. However, light in the angle region exceeding the critical angle is directed toward the vertical at the verticalized moth eye surface 102a, and thus the light absorbed in the element can be reduced drastically.

Here, the present inventors have found out that, by using the combination of the dielectric multilayer film 124 and the metal layer 126 as the reflection unit at the back surface of the sapphire substrate 102, the light extraction efficiency of the LED element 101 increases substantially. Namely, when the dielectric multilayer film 124 and the metal layer 126 are combined, the reflectivity increases as the angle comes closer to the vertical with respect to the interface, which attains favorable reflection condition for the light directed toward the vertical with respect to the interface.

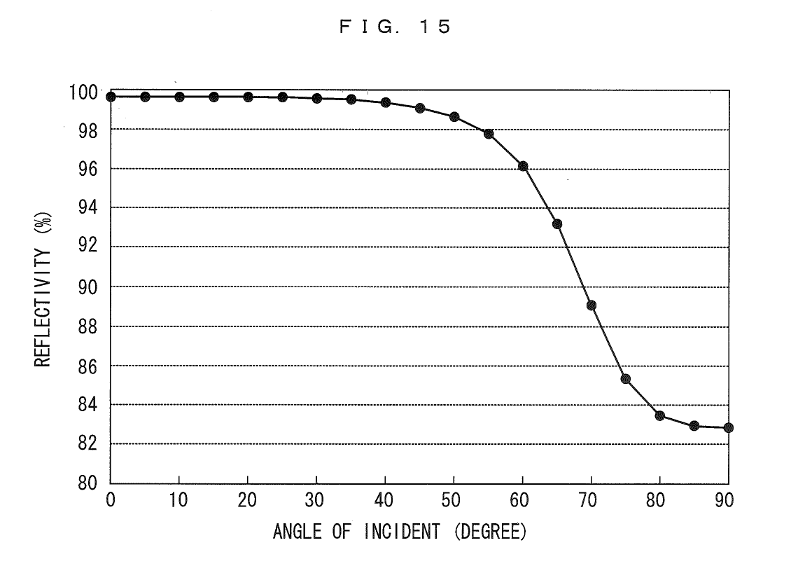

FIG. 15 is a graph illustrating the reflectivity of a reflection unit according to an example 3. According to the example 3, five pairs of ZrO₂ and SiO₂ are combined to form the dielectric multilayer film formed on the sapphire substrate, and the Al layer is formed to overlap the dielectric multilayer film. As illustrated in FIG. 15, the reflectivity of 99% or more is realized in the angle region where the angle of incident is from 0 degree to 55 degrees. Furthermore, the reflectivity of 98% or more is realized in the angle region where the angle of incident is from 0 degree to 60 degrees. Furthermore, the reflectivity of 92% or more is realized in the angle region where the angle of incident is from 0 degree to 75 degrees. Thus, the combination of the dielectric multilayer film and the metal layer attains the favorable reflection condition for the light directed toward the vertical with respect to the interface.

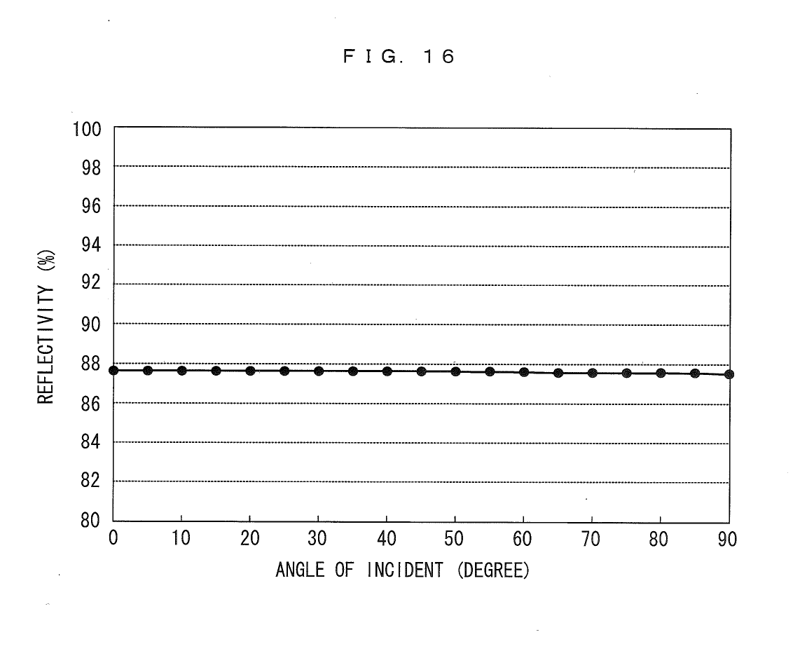

FIG. 16 is a graph illustrating the reflectivity of a reflection unit according to an example 4. According to the example 4, only the Al layer is formed on the sapphire substrate. As illustrated in FIG. 16, the reflectivity shows 88% almost constantly, irrespective of the angle of incident. Thus, the reflection unit may be a single layer of metal, such as the Al layer.

According to the above-described embodiments, the structure of the verticalized moth eye surface and the transmission moth eye surface having the periodically-formed projection parts is illustrated, but it is needless to say that the respective moth eye surfaces may be formed to have depression parts that are formed periodically. In addition, the projection parts or the depression parts may be formed to align at points of intersection of a virtual square lattice, for example, not only at the points of intersection of the triangle lattice.

Further, the specific structure of the LED element is not limited as those of the above-described embodiments. Namely, an LED element may include a sapphire substrate, and a semiconductor lamination unit that is formed on a front surface of the sapphire substrate and that includes a light-emitting layer, in which the front surface of the sapphire substrate fauns a verticalized moth eye surface having a plurality of depression parts or projection parts whose period is greater than twice an optical wavelength of light emitted from the light-emitting layer and smaller than coherent length, in which the verticalized moth eye surface reflects and transmits light being incident on the verticalized moth eye surface from a side of the semiconductor lamination unit, and is configured in such a manner that, in an angle region exceeding a critical angle, intensity distribution of light emitted from the verticalized moth eye surface on the side of the semiconductor lamination unit is inclined to direction closer to vertical direction with respect to an interface between the semiconductor lamination unit and the sapphire substrate, as compared with the intensity distribution of light being incident on the verticalized moth eye surface on the side of the semiconductor lamination unit, and that, in the angle region exceeding the critical angle, the intensity distribution of light emitted from the verticalized moth eye surface on a side of the sapphire substrate is inclined to direction closer to the vertical direction with respect to the interface, as compared with the intensity distribution of light being incident on the verticalized moth eye surface on the side of the semiconductor lamination unit, in which a reflection unit that reflects light transmitting through the verticalized moth eye surface is provided, in which a transmission moth eye surface having depression parts or projection parts whose period is smaller than twice the optical wavelength of light emitted from the light-emitting layer is provided, and in which the light, whose intensity distribution is adjusted by reflecting on and transmitting through the verticalized moth eye surface to be inclined to the vertical direction with respect to the interface, is discharged from the transmission moth eye surface to an outer side of the element with Fresnel reflection being inhibited.

### INDUSTRIAL APPLICABILITY

The LED element according to the present invention can further improve the light extraction efficiency and therefore it is industrially usable.

### REFERENCE SIGNS LIST

1 LED element
2 Sapphire substrate
2a Verticalized moth eye surface
2b Flat part
2c Projection part
2d Side surface
2e Bent portion
2f Top surface
2g Transmission moth eye surface
2h Flat part
2i Projection part
10 Buffer layer
12 N-type GaN layer
14 Light-emitting layer
16 Electron blocking layer
18 P-type GaN layer
19 Semiconductor lamination unit
21 Diffusion electrode
22 Dielectric multilayer film
22a First material
22b Second material
22c Via hole
23 Metal electrode
24 Diffusion electrode
25 Dielectric multilayer film
25a Via hole
26 Metal electrode
27 P-side electrode
28 N-side electrode
30 Mask layer
31 SiO₂ layer
32 Ni layer
40 Resist film
41 Projection-and-depression structure
42 Residual film
43 Projection part
50 Mold
51 Projection-and-depression structure
91 Plasma etching apparatus
92 Substrate holding table
93 Container
94 Coil
95 Power supply
96 Quartz plate
97 Cooling control unit
98 Plasma
101 LED element
102 Sapphire substrate
102a Verticalized moth eye surface
110 Buffer layer
112 N-type GaN layer
114 Light-emitting layer
116 Electron blocking layer
118 P-type GaN layer
119 Semiconductor lamination unit
122 Pad electrode
124 Dielectric multilayer film
124a First material
124b Second material
126 Al layer
127 P-side electrode
128 N-side electrode

1. An LED element of a flip chip type, comprising:
a sapphire substrate;
a semiconductor lamination unit that is formed on a front surface of the sapphire substrate and that includes a light-emitting layer; and
a reflection unit that is formed on the semiconductor lamination unit,
wherein the front surface of the sapphire substrate forms a verticalized moth eye surface having a plurality of depression parts or projection parts whose period is greater than twice an optical wavelength of light emitted from the light-emitting layer and smaller than coherent length,
wherein a back surface of the sapphire substrate forms a transmission moth eye surface having depression parts or projection parts whose period is smaller than twice the optical wavelength of light emitted from the light-emitting layer,
wherein the verticalized moth eye surface reflects and transmits light being incident on the verticalized moth eye surface from a side of the semiconductor lamination unit, and is configured in such a manner that, in an angle region exceeding a critical angle, intensity distribution of light emitted by reflection from the verticalized moth eye surface on the side of the semiconductor lamination unit is inclined to direction closer to vertical direction with respect to an interface between the semiconductor lamination unit and the sapphire substrate, as compared with the intensity distribution of light being incident on the verticalized moth eye surface on the side of the semiconductor lamination unit, and that, in the angle region exceeding the critical angle, the intensity distribution of light emitted by transmission from the verticalized moth eye surface on a side of the sapphire substrate is inclined to direction closer to the vertical direction with respect to the interface, as compared with the intensity distribution of light being incident on the verticalized moth eye surface on the side of the semiconductor lamination unit, and
wherein the light, whose intensity distribution is adjusted by reflecting on and transmitting through the verticalized moth eye surface to be inclined to the vertical direction with respect to the interface, is discharged from the transmission moth eye surface to an outer side of the element with Fresnel reflection being inhibited.

2. The LED element of the flip chip type according to claim 1,
wherein reflectivity of the reflection unit increases as an angle comes closer to the direction vertical to the interface.

3. A manufacturing method of an LED element for manufacturing the LED element according to claim 2, the manufacturing method comprising:
a mask layer formation process that forms a mask layer on a front surface of a sapphire substrate;
a resist film formation process that forms a resist film on the mask layer;
a pattern formation process that forms a predetermined pattern on the resist film;
a resist alteration process that guides plasma of an Ar gas to a side of the sapphire substrate by applying predetermined bias output, and that alters the resist film by the plasma of the Ar gas, so as to increase etch selectivity;
a mask layer etching process that guides the plasma of the Ar gas to the side of the sapphire substrate by applying bias output higher than the bias output of the resist alteration process, and that uses the resist film, whose etch selectivity is increased, as a mask, so as to etch the mask layer;
a substrate etching process that uses the etched mask layer as a mask, and that etches the sapphire substrate, so as to form the depression parts or the projection parts;
a semiconductor formation process that forms the semiconductor lamination unit on the etched front surface of the sapphire substrate; and
a multilayer formation process that forms the dielectric multilayer film on a back surface of the sapphire substrate.

4. The manufacturing method of the LED element according to claim 3,
wherein, in the substrate etching process, the sapphire substrate is etched while the resist film remains on the mask layer.

5. The manufacturing method of the LED element according to claim 4,
wherein the mask layer includes a SiO₂ layer on the sapphire substrate and a Ni layer on the SiO₂ layer, and
wherein, in the substrate etching process, the sapphire substrate is etched while the SiO₂ layer, the Ni layer, and the resist film are laminated.

6. An LED element of a face-up type, comprising:
a sapphire substrate;
a semiconductor lamination unit that is formed on a front surface of the sapphire substrate and that includes a light-emitting layer;
a reflection unit that is formed on a back surface of the sapphire substrate; and
an electrode that is formed on the semiconductor lamination unit,
wherein the front surface of the sapphire substrate forms a verticalized moth eye surface having a plurality of depression parts or projection parts whose period is greater than twice an optical wavelength of light emitted from the light-emitting layer and smaller than coherent length,
wherein a front surface of the electrode forms a transmission moth eye surface having depression parts or projection parts whose period is smaller than twice the optical wavelength of light emitted from the light-emitting layer,
wherein the verticalized moth eye surface reflects and transmits light being incident on the verticalized moth eye surface from a side of the semiconductor lamination unit, and is configured in such a manner that, in an angle region exceeding a critical angle, the intensity distribution of light emitted by reflection from the verticalized moth eye surface on the side of the semiconductor lamination unit is inclined to direction closer to vertical direction with respect to an interface between the semiconductor lamination unit and the sapphire substrate, as compared with the intensity distribution of light being incident on the verticalized moth eye surface on the side of the semiconductor lamination unit, and that, in the angle region exceeding the critical angle, the intensity distribution of light emitted by transmission from the verticalized moth eye surface on a side of the sapphire substrate is inclined to direction closer to the vertical direction with respect to the interface, as compared with the intensity distribution of light being incident on the verticalized moth eye surface on the side of the semiconductor lamination unit, and
wherein the light, whose intensity distribution is adjusted by reflecting on and transmitting through the verticalized moth eye surface to be inclined to the vertical direction with respect to the interface, is discharged from the transmission moth eye surface to an outer side of the element with Fresnel reflection being inhibited.

7. An LED element comprising:
a sapphire substrate; and
a semiconductor lamination unit that is formed on a front surface of the sapphire substrate and that includes a light-emitting layer,
wherein the front surface of the sapphire substrate forms a verticalized moth eye surface having a plurality of depression parts or projection parts whose period is greater than twice an optical wavelength of light emitted from the light-emitting layer and smaller than coherent length,
wherein the verticalized moth eye surface reflects and transmits light being incident on the verticalized moth eye surface from a side of the semiconductor lamination unit, and is configured in such a manner that, in an angle region exceeding a critical angle, the intensity distribution of light emitted by reflection from the verticalized moth eye surface on the side of the semiconductor lamination unit is inclined to direction closer to vertical direction with respect to an interface between the semiconductor lamination unit and the sapphire substrate, as compared with the intensity distribution of light being incident on the verticalized moth eye surface on the side of the semiconductor lamination unit, and that, in the angle region exceeding the critical angle, the intensity distribution of light emitted by transmission from the verticalized moth eye surface on a side of the sapphire substrate is inclined to direction closer to the vertical direction with respect to the interface, as compared with the intensity distribution of light being incident on the verticalized moth eye surface on the side of the semiconductor lamination unit,
wherein a reflection unit that reflects light transmitting through the verticalized moth eye surface is provided,
wherein a transmission moth eye surface having depression parts or projection parts whose period is smaller than twice the optical wavelength of light emitted from the light-emitting layer is provided, and
wherein the light, whose intensity distribution is adjusted by reflecting on and transmitting through the verticalized moth eye surface to be inclined to the vertical direction with respect to the interface, is discharged from the transmission moth eye surface to an outer side of the element with Fresnel reflection being inhibited.
